(19) United States
(12) Patent Application Publication
(10) Pub. No.: US 2022/0336210 A1
(43) Pub. Date: Oct. 20, 2022

(54) CLEANING COMPOSITION

(71) Applicant: ENTEGRIS, INC., Billerica, MA (US)

(72) Inventors: Jun Liu, Newtown, CT (US); Michael L. White, Ridgefield, CT (US); Daniela White, Ridgefield, CT (US); Emanuel I. Cooper, Scarsdale, NY (US)

(21) Appl. No.: 17/720,580

(22) Filed: Apr. 14, 2022

Related U.S. Application Data
(60) Provisional application No. 63/175,965, filed on Apr. 16, 2021.

(51) Int. Cl. H01L 21/02

(52) U.S. Cl. CPC H01L 21/02065; H01L 21/02063; H01L 21/02074; C11D 7/36

(57) ABSTRACT

Provided are compositions useful for the cleaning of microelectronic device structures. The residues may include post-CMP, post-etch, post-ash residues, pad and brush debris, metal and metal oxide particles and precipitated metal organic complexes such as copper-benzotriazole complexes. Advantageously, the compositions as described herein show improved aluminum, cobalt, and copper compatibility.

### CROSS-REFERENCE TO RELATED APPLICATIONS

This application claims the benefit under 35 USC 119 of U.S. Provisional Patent Application No. 63/142,849 filed Apr. 16, 2021, the disclosure of which is hereby incorporated herein by reference in its entirety.

### TECHNICAL FIELD

The invention relates generally to the field of microelectronic device manufacturing. In particular, it relates to a post-CMP cleaning composition.

### BACKGROUND

Microelectronic device wafers are used to form integrated circuits and includes a substrate, such as silicon, into which regions are patterned for deposition of different materials having insulative, conductive or semi-conductive properties.

In order to obtain the correct patterning, excess material used in forming the layers on the substrate must be removed. Further, to fabricate functional and reliable circuitry, it is important to prepare a flat or planar microelectronic wafer surface prior to subsequent processing. Thus, it is necessary to remove and/or polish certain surfaces of a microelectronic device wafer.

Chemical mechanical polishing or planarization (“CMP”) is a process in which material is removed from a surface of a microelectronic device wafer, and the surface is polished (more specifically, planarized) by coupling a physical process such as abrasion with a chemical process such as oxidation or chelation. Fundamentally, CMP involves applying a slurry, such as a combination of an abrasive in an aqueous solution containing active chemistry, to a polishing pad that buffs the surface of a microelectronic device wafer to achieve the removal, planarization, and polishing processes. The synergistic combination of physical and chemical action achieves fast, uniform removal. In the fabrication of integrated circuits, the CMP slurry should also be able to preferentially remove films that comprise complex layers of metals and other materials so that highly planar surfaces can be produced for subsequent photolithography, or patterning, etching and thin-film processing. One key to obtaining good uniformity across the wafer surface after polishing is to use a CMP slurry that has the correct removal selectivities for each of the materials present.

Most of the processing operations, including wafer substrate surface preparation, deposition, plating, etching and chemical mechanical polishing, require cleaning operations to ensure that the microelectronic device product is free of contaminants that would otherwise deleteriously affect the function of the product, or even render it useless for its intended function. Often, particles of these contaminants are smaller than 0.3 μm. If not removed, these residues can cause damage to, for example, copper lines or severely roughen copper metallization, as well as cause poor adhesion of post-CMP applied layers on the device substrate.

There is a continuing need in the industry to provide compositions and methods that affectively and selectively remove various residues from a substrate, e.g., post-CMP residue, post-etch residue, and post-ash residue, particularly as demand increases for improved device performance and for decreased device sizes and decreased device feature sizes. The compositions and methods should eliminate particles and other contaminants as well as not appreciably corrode, or otherwise damage components such as aluminum, cobalt, and copper.

### SUMMARY

Aluminum is used as a back end of the line interconnect (BEOL), along with materials such as copper, cobalt, ruthenium, manganese, molybdenum, rhenium, titanium nitride, tantalum nitride, tungsten nitride, silicon dioxide, silicon nitride, silicon carbide, silicon carbonitride, low k dielectrics, polysilicon, and silsequioxane- or siloxane-based dielectrics.

In summary, the present invention relates to a composition and method for cleaning residue and/or contaminants from microelectronic devices having said residue and contaminants thereon. The residues may include post-CMP, post-etch, post-ash residues, pad and brush debris, metal and metal oxide particles and precipitated metal organic complexes such as copper-benzotriazole complexes.

Advantageously, the compositions as described herein show improved compatibility with certain metals such as aluminum, cobalt, and copper.

In one aspect, the invention provides a composition comprising water; an etchant compound; a pH adjustor; and a corrosion inhibitor chosen from certain phosphorous-containing compounds.

### DETAILED DESCRIPTION OF THE INVENTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

The present invention relates generally to compositions useful for the removal of residue and contaminants from a microelectronic device substrate having such material(s) thereon. The compositions are particularly useful for the removal of post-CMP, post-etch, or post-ash residue from aluminum-containing substrates without appreciably damaging the bulk aluminum thereon.

The term “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

As used herein, “residue” corresponds to particles generated during the manufacture of a microelectronic device including, but not limited to, plasma etching, ashing, chemical mechanical polishing, wet etching, and combinations thereof.

As used herein, “contaminants” correspond to chemicals present in the CMP slurry, reaction by-products of the polishing slurry, chemicals present in the wet etching composition, reaction by products of the wet etching composition, and any other materials that are the by-products of the CMP process, the wet etching, the plasma etching or the plasma ashing process such as pad and brush debris, metal and metal oxide particles and precipitated metal organic complexes such as copper-benzotriazole complexes.

As used herein, “post-etch residue” corresponds to material remaining following gas-phase plasma etching processes, e.g., BEOL dual damascene processing, or wet etching processes. The post-etch residue may be organic, organometallic, organosilicic, or inorganic in nature, for example, silicon-containing material, carbon-based organic material, and etch gas residue such as oxygen and fluorine.

As used herein, “post-ash residue,” corresponds to material remaining following oxidative or reductive plasma ashing to remove hardened photoresist and/or bottom anti-reflective coating (BARC) materials. The post-ash residue may be organic, organometallic, organosilicic, or inorganic in nature.

As used herein, “post-CMP residue” corresponds to particles from the polishing slurry, e.g., silica-containing particles, chemicals present in the slurry, reaction by-products of the polishing slurry, carbon-rich particles, polishing pad particles, brush deloading particles, equipment materials of construction particles, metals, metal oxides, organic residues, barrier layer residues, and any other materials that are the by-products of the CMP process. As defined herein, the “metals” that are typically polished include copper, aluminum and cobalt.

As used herein, the term “low-k dielectric material” corresponds to any material used as a dielectric material in a layered microelectronic device, wherein the material has a dielectric constant less than about 3.5. In certain embodiments, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As used herein, the term “barrier material” corresponds to any material used in the art to seal the metal lines, e.g., copper interconnects, to minimize the diffusion of said metal, e.g., copper, into the dielectric material. Barrier layer materials include tantalum, titanium, ruthenium, hafnium, tungsten, cobalt, and nitrides, carbides, and silicides of any of the foregoing metals.

As used herein, “reaction or degradation products” include, but are not limited to, product(s) or by-product(s) formed as a result of catalysis at a surface, oxidation, reduction, reactions with the compositional components, or that otherwise polymerize; product(s) or by-product(s) formed as a result of a change(s) or transformation(s) in which a substance or material (e.g., molecules, compounds, etc.) combines with other substances or materials, interchanges constituents with other substances or materials, decomposes, rearranges, or is otherwise chemically and/or physically altered, including intermediate product(s) or by-product(s) of any of the foregoing or any combination of the foregoing reaction(s), change(s) and/or transformation(s).

As used herein, “complexing agent” includes those compounds that are understood by one skilled in the art to be complexing agents, chelating agents and/or sequestering agents. Complexing agents will chemically combine with, coordinate with, or physically hold the metal atom and/or metal ion to be removed using the compositions described herein.

As used herein, “fluoride containing compounds” correspond to salt or acid compound comprising a fluoride ion (F—) that is ionically bonded to another atom.

“Substantially devoid” is defined herein as less than 2 weight. %, less than 1 weight. %, less than 0.5 weight %, or less than 0.1 weight. %. In one embodiment, “substantially devoid” corresponds to zero percent, indicating the composition is free of a particular component.

As used herein, “suitability” for cleaning residue and contaminants from a microelectronic device having said residue and contaminants thereon corresponds to at least partial removal of said residue/contaminants from the microelectronic device. Cleaning efficacy is rated by the reduction of objects on the microelectronic device. For example, pre- and post-cleaning analysis may be carried out using an atomic force microscope. The particles on the sample may be registered as a range of pixels. A histogram (e.g., a Sigma Scan Pro) may be applied to filter the pixels in a certain intensity, e.g., 231-235, and the number of particles counted. The particle reduction may be calculated using:

$$Cleaning Efficacy = \frac{( Number of PreClean Objects - Number of PostClean Objects )}{Number of PreClean objects} \times 100$$

Notably, the method of determination of cleaning efficacy is provided for example only and is not intended to be limited to same. Alternatively, the cleaning efficacy may be considered as a percentage of the total surface that is covered by particulate matter. For example, atomic force microscopy devices may be programmed to perform a z-plane scan to identify topographic areas of interest above a certain height threshold and then calculate the area of the total surface covered by said areas of interest. One skilled in the art would readily understand that the less area covered by said areas of interest post-cleaning, the more efficacious the cleaning composition. In certain embodiments, at least 75%, at least 90%, at least 95%, or at least 99% of the residue/contaminants are removed from the microelectronic device using the compositions described herein.

Compositions described herein may be embodied in a wide variety of specific formulations, as hereinafter more fully described.

The compositions of the invention are in certain embodiments substantially devoid, or devoid, of fluoride-containing sources, abrasive materials, tetramethylammonium hydroxide (TMAH), and combinations thereof, prior to use in the removal of residue material from the microelectronic device.

The compositions of the invention comprise, consist of, or consist essentially of water, a reducing agent, an etchant compound, and an aluminum, copper, and/or cobalt corrosion inhibitor chosen from certain phosphorous-containing compounds. Advantageously, the compositions increase the removal of contaminants and residue (e.g., benzotriazole, slurry particles and other post-CMP residues) remaining on exposed aluminum-containing surface on a microelectronic device while simultaneously lowering the corrosion rate of exposed aluminum, copper, or cobalt surfaces.

In a first aspect, the invention provides a composition comprising:
a) water;
b) an etchant compound;
c) a reducing agent; and
d) an aluminum, cobalt, or copper corrosion inhibitor chosen from compounds having the formula

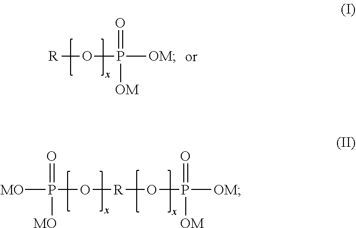

wherein each x is independently 0 or 1, R is an aryl or arylene group or a monovalent or divalent C₁-C₂₀ hydrocarbyl group, and M is chosen from hydrogen, a C₁-C₆ alkyl group, ammonium, or an alkali metal cation, and wherein the pH of the composition is greater than about 8.

As used herein, the term “C₁-C₂₀ hydrocarbyl group” refers to alkyl, alkylene, alkenyl, alkylidene, aryl or arylene groups having from one to 20 carbons or a polymeric carbon backbone, optionally substituted by one or more groups chosen from C₁-C₆ alkyl, C₁-C₆ alkoxy, C₂-C₆ alkenyl, C₃-C₈ cycloalkyl, C₁-C₆ carboxy, C₁-C₆ alkoxycarbonyl, C₁-C₆ alkanoyloxy, hydroxy, halo, cyano, aryl, and heteroaryl. Specific examples include linear, branched, or cyclic alkyl or alkylene groups as well as phenyl or phenylene groups. Additionally, the compound(s) of formula (I) and (II) may be present as a mixture of two or more compounds of formula (I) and/or (II).

In one embodiment, the compounds of formula (I) and (II) are chosen from:
phenylphosphonic acid;
phytic acid;
(12-phosphonododecyl)phosphonic acid;
n-dodecylphosphonic acid;
6-phosphonohexanoic acid;
1,4-phenylenebis(phosphonic acid);
poly(vinylphosphonic acid);
octylphosphonic acid;
tetraisopropyl vinylidenediphosphonate;
potassium di-tert-butylphosphate;
ethylphosphonic acid;
methylenediphosphonic acid;
1,10-decyldiphosphonic acid;
octylphosphonic acid;
hexylphosphonic acid;
octadecylphosphonic acid;
n-dodecylphosphonic acid; and
mono-N-dodecyl phosphate.

In the compositions, the etchant compounds (or “etchants”) are believed to function as complexing agents. In some embodiments, the composition may comprise an etchant component comprising a plurality of etchants. Illustrative etchants agents can include species having the general formula NR¹R²R³, wherein R¹, R² and R³ may be the same as or different from one another and are chosen from hydrogen, straight-chain or branched C₁-C₆ alkyl (e.g., methyl, ethyl, propyl, butyl, pentyl, and hexyl) groups, straight-chain or branched C₁-C₆ hydroxyalkyl (e.g., hydroxymethyl, hydroxyethyl, hydroxypropyl, hydroxybutyl, hydroxypentyl, and hydroxyhexyl) groups, and C₁-C₆ alkyl ethers of straight chain or branched C₁-C₆ hydroxyalkyl groups as defined above. In certain embodiments, at least one of R¹, R² and R³ is a straight-chain or branched C₁-C₆ hydroxyalkyl group. Examples include, without limitation, alkanolamines such as aminoethylethanolamine, N-methylaminoethanol, aminoethoxyethanol, dimethylaminoethoxyethanol, diethanolamine, N-methyldiethanolamine, monoethanolamine (MEA), triethanolamine (TEA), isopropanolamine, diisopropanolamine, aminopropyldiethanolamine, N,N-dimethylpropanolamine, N-methylpropanolamine, 1-amino-2-propanol, 2-amino-1-butanol, 3-amino-4-octanol, isobutanolamine, triethylenediamine, diglycol amine, other C₁-C₈ alkanolamines, and ethylene oxide or propylene oxide-based polymeric Jeffamines, and combinations thereof. When the amine includes the alkylether component, the amine may be considered an alkoxylamine, e.g., 1-methoxy-2-aminoethane.

Alternatively, or in addition to the NR¹R²R³ amine, the etchant compound agent may be a multi-functional amine including, but not limited to, 4-(2-hydroxyethyl)morpholine (HEM), 1,2-cyclohexanediamine-N,N,N′,N′-tetraacetic acid (CDTA), ethylenediaminetetraacetic acid (EDTA), m-xylenediamine (MXDA), iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, and combinations thereof.

Alternatively, or in addition to the aforementioned etchants, additional etchant compounds can include 1,5,9-triazacyclododecane-N,N′,N″-tris(methylenephosphonic acid) (DOTRP), 1,4,7,10-tetraazacyclododecane-N,N′,N″,N′″-tetrakis(methylenephosphonic acid) (DOTP), nitrilotris(methylene)triphosphonic acid, diethylenetriaminepentakis(methylenephosphonic acid) (DETAP), aminotri(methylenephosphonic acid), bis(hexamethylene)triamine pentamethylene phosphonic acid, 1,4,7-triazacyclononane-N,N′,N″-tris(methylenephosphonic acid (NOTP), hydroxyethyldiphosphonate, nitrilotris(methylene)phosphonic acid, 2-phosphono-butane-1,2,3,4-tetracarboxylic, carboxyethyl phosphonic acid, aminoethyl phosphonic acid, glyphosate, ethylene diamine tetra(methylenephosphonic acid) phenylphosphonic acid, salts thereof, and derivatives thereof) and/or carboxylic acids (e.g., oxalic acid, succinic acid, maleic acid, malic acid, malonic acid, adipic acid, phthalic acid, citric acid, sodium citrate, potassium citrate, ammonium citrate, tricarballylic acid, dimethylolpropionic acid, trimethylolpropionic acid, tartaric acid, acetyl acetone, glutamic acid, adipic acid, amino tris(methylenephosphonic) acid; thiourea, 1,1,3,3-tetramethylurea, urea, urea derivatives, uric acid, alanine, arginine, taurine, and combinations thereof. glucuronic acid, 2-carboxypyridine) and/or sulfonic acids such as 4,5-dihydroxy-1,3-benzenedisulfonic acid disodium salt. In one embodiment, the etchant may be chosen from monoethanolamine, triethanolamine, sulfuric acid, citric acid and combinations thereof.

The amount of etchant compound(s) in the composition is in one embodiment, in a range from about 0.005 wt % to about 20 wt %, based on the total weight of the cleaning composition. In another embodiment, the etchant is present in an amount of from about 0.01 wt % to about 10 wt %, based on the total weight of the cleaning composition, and, in another embodiment, in an amount of from about 0.01 wt % to about 25 wt %.

The compositions comprise one or more reducing agents. Illustrative reducing agents include, but are not limited to, ascorbic acid, L(+)-ascorbic acid, isoascorbic acid, ascorbic acid derivatives, hypophosphorous acid (H₃PO₂), hydroxyl amines such as DEHA (diethylhydroxylamine), reducing sugars (for example, galactose), xylose, sorbitol, sulfurous acid, ammonium sulfite, potassium sulfite, sodium sulfite, dopamine HCl, phosphorous acid, phosphinic acid, hypophosphorous acid, potassium metabisulfite, sodium metabisulfite, ammonium metabisulfite, potassium pyruvate, sodium pyruvate, ammonium pyruvate, formic acid, sodium formate, potassium formate, ammonium formate, dopamine, sulfur dioxide solution, and any combination thereof. For example, the reducing agent may comprise at least one sulfite ion and at least one other enumerated reducing agent, for example, sulfurous acid, potassium sulfite, ammonium sulfite, phosphinic acid, resorcinols, i.e, 1,1-dihyroxy benzene, 1, 3-dihydroxy benzene, and 1,4-dihydroxy benzene, and any combination thereof. When ammonium sulfite is present, the ammonium sulfite can be produced in situ, wherein the combination of specific components results in the formation of ammonium sulfite to assist with the removal of residue, e.g., abrasive particles such as silica particles and other post-CMP residue(s).

In another embodiment, the reducing agent, when present is chosen from N-aminomorpholine, N-aminopiperazine, hydroquinone, catechols, tetrahydrofulvalene, N,N-dimethylanilinebenzylamine, hydroxylamines and other sulfur based reducing agents.

In another embodiment, the reducing agent is chosen from hydrophosphorous acid, phosphorous acid, sulfurous acid, sodium metabisulfite, ammonium metabisulfite, potassium metabisulfite, ascorbic acid, L(+)-ascorbic acid, isoascorbic acid, hydroxylamine, hydroxylamine salts, dimethylhydroxylamine, diethylhydroxylamine, reducing sugars chosen from galactose, xylose, glucose, fructose, lactose and maltose, hydroquinone, catechol, tetrahydrofulvalene, N,N-dimethylanilinebenzylamine, and combinations thereof.

In various embodiments, the amount of reducing agent in the composition is in the range of from about 0.0001 wt % to about 20 wt % based on the total weight of the composition. In another embodiment, the reducing agent is present in an amount of from about 0.0001 wt % to about 10 wt %, based on the total weight of the composition, and, in yet other embodiments, in an amount of from 0.01 wt % to 6 wt %, or 0.005 wt % to 5 wt %. In one embodiment, the reducing agent is ascorbic acid. In various embodiments, the cleaning composition does not contain a reducing agent.

As noted above, the pH of the composition is greater than about 8. In another embodiment, the pH is less than about 14. In another embodiment, the pH is about 8.5 to about 12. In another embodiment, component d) is an aluminum corrosion inhibitor and the pH is about 8 to 11. In another embodiment, component d) is a cobalt corrosion inhibitor and the pH is about 8 to about 13.5. In order to reach the desired target pH, the composition may further comprise one or more pH adjusting agents. In one embodiment, the pH adjusting agent is a base and is used to raise the pH of the cleaning composition. Illustrative bases include, but are not limited to, alkali metal hydroxides (e.g., LiOH, KOH, RbOH, CsOH), alkaline earth metal hydroxides (e.g., Be(OH)₂, Mg(OH)₂, Ca(OH)₂, Sr(OH)₂, Ba(OH)₂), ammonium hydroxide (i.e., ammonia), and a tetraalkylammonium hydroxide compound having the formula NR¹R²R³R⁴OH, wherein R¹, R², R³ and R⁴ may be the same as or different from one another and are selected from the group consisting of hydrogen, straight-chain or branched C₁-C₆ alkyl (e.g., methyl, ethyl, propyl, butyl, pentyl, and hexyl) groups, C₁-C₆ hydroxyalkyl (e.g., hydroxymethyl, hydroxyethyl, hydroxypropyl, hydroxybutyl, hydroxypentyl, and hydroxyhexyl) groups, and substituted or unsubstituted C₆-C₁₀ aryl groups (e.g., benzyl groups). Tetraalkylammonium hydroxides that are commercially available include tetramethylammonium hydroxide (TMAH), tetraethylammonium hydroxide (TEAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, and combinations thereof, may be used.

Alternatively or in addition, the pH adjustor agent may be a quaternary base having the formula (PR¹R²R³R⁴)OH, wherein R¹, R², R³, and R⁴ may be the same as or different from one another and are chosen from hydrogen, straight-chain C₁-C₆ alkyl (e.g., methyl, ethyl, propyl, butyl, pentyl, and hexyl) groups, branched C₁-C₆ alkyl groups, C₁-C₆ hydroxyalkyl (e.g., hydroxymethyl, hydroxyethyl, hydroxypropyl, hydroxybutyl, hydroxypentyl, and hydroxyhexyl) groups, substituted C₆-C₁₀ aryl groups, unsubstituted C₆-C₁₀ aryl groups (e.g., benzyl groups), and any combination thereof, such as tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, N-propyl triphenylphosphonium hydroxide.

In one embodiment, the pH adjustor is chosen from TMAH, TEAH, choline hydroxide, ammonium hydroxide, and potassium hydroxide.

The amount of pH adjusting compound(s) added is dependent on the desired pH, as disclosed herein and as understood by the person skilled in the art. For example, the pH adjusting agent may be present in an amount of from about 0.1 wt % to about 10 wt %, based on the total weight of the cleaning composition, or in an amount of from about 1 wt % to about 5 wt %.

In certain embodiments, the composition may further comprise certain cleaning additive components chosen from solvents, water soluble polymers, and/or surfactants.

Illustrative cleaning additives include, but are not limited to solvents such as 2-pyrrolidinone, 1-(2-hydroxyethyl)-2-pyrrolidinone (HEP), methanol, ethanol, isopropanol, butanol, and higher alcohols (such as C₂-C₄ diols and C₂-C₄ triols), tetrahydrofurfuryl alcohol (THFA), halogenated alcohols (such as 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, 2-chloroethanol), dichloromethane, chloroform, glycerol, 1,4-butanediol, tetramethylene sulfone (sulfolane), dimethyl sulfone, ethylene glycol, propylene glycol, dipropylene glycol, tetraglyme, diglyme, methyl isobutyl ketone, methyl ethyl ketone, acetone, isopropanol, octanol, ethanol, butanol, methanol, isophorone, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (DEGBE), triethylene glycol monobutyl ether (TEGBE), ethylene glycol monohexyl ether (EGHE), diethylene glycol monohexyl ether (DEGHE), ethylene glycol phenyl ether, diethylene glycol phenylether, hexaethylene glycol monophenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether (such as DOWANOL PnB), dipropylene glycol n-butyl ether, tripropylene glycol n-butyl ether, dipropylene glycol phenyl ether, propylene glycol phenyl ether (PPh, such as DOWANOL™ PPh), 4-methyl-2-pentanone, 2,4-dimethyl-3-pentanone, cyclohexanone, 5-methyl-3-heptanone, 3-pentanone, 5-hydroxy-2-pentanone, 2,5-hexanedione, 4-hydroxy-4-methyl-2-pentanone, acetone, butanone, 2-methyl-2-butanone, 3,3-dimethyl-2-butanone, 4-hydroxy-2-butanone, cyclopentanone, 2-pentanone, 3-pentanone, 1-phenylethanone, acetophenone, benzophenone, 2-hexanone, 3-hexanone, 2-heptanone, 3-heptanone, 4-heptanone, 2,6-dimethyl-4-heptanone, 2-octanone, 3-octanone, 4-octanone, dicyclohexyl ketone, 2,6-dimethylcyclohexanone, 2-acetylcyclohexanone, 2,4-pentanedione, menthone, dimethylsulfoxide (DMSO), dimethylformamide (DMF), N-methylpyrrolidinone (NMP), propylene urea, N, N′-dimethylpropyleneurea, cyclohexylpyrrolidinone, N-octylpyrrolidinone, N-phenylpyrrolidinone, ethylene carbonate, propylene carbonate, cyrene, dimethylethyleneurea, propiophenone, ethyl lactate, ethyl acetate, ethyl benzoate, acetonitrile, acetone, ethylene glycol, propylene glycol (PG), 1,3-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, ethylene glycol monophenyl ether, diethylene glycol monophenyl ether hexaethylene glycol monophenylether, dipropylene glycol methyl ether acetate, tetraethylene glycol dimethyl ether (TEGDE), dibasic ester, glycerine carbonate, N-formyl morpholine, triethyl phosphate, and combinations thereof.

Alternatively, or in addition, the cleaning additive may include water soluble polymers including, for example, acrylic or methacrylic acid homopolymers and copolymers with, for example, acrylamidomethylpropane sulfonic acid and maleic acid and salts thereof; maleic acid/vinyl ether copolymer; poly(vinylpyrrolidone)/vinyl acetate; homopolymers such as phosphonated polyethyleneglycol oligomers, poly(acrylic acid) (PAA), poly(acrylamide), poly(vinyl acetate), poly(ethylene glycol) (PEG), poly(propylene glycol) (PPG), poly(styrene sulfonic acid), poly(vinyl sulfonic acid), poly(vinyl phosphonic acid), poly(vinyl phosphoric acid), poly(ethyleneimine), poly(propyleneimine), polyallylamine, polyethylene oxide (PEO), polyvinyl pyrrolidone (PVP), poly(vinyl alcohol), hydrophilic water soluble or dispersible polyurethanes, poly(ethylene glycol acrylate), poly(ethylene glycol methacrylate), PPG-PEG-PPG block copolymers, PEG-PPG-PEG block copolymers, and combinations thereof.

Alternatively, or in addition, when present the cleaning additive may be a surfactant, including, but not limited to anionic, non-ionic, cationic and/or zwitterionic surfactants.

Examples of such surfactants include alginic acid and salts thereof; hydroxyl or carboxyalkylcellulose; dextran sulfate and salts thereof; poly(galacturonic acid) and salts thereof; homopolymers of (meth)acrylic acid and salts thereof, maleic acid, maleic acid anhydride, styrene sulfonic acid and salts thereof, vinyl sulfonic acid and salts thereof, allyl sulfonic acid and salts thereof, acrylamidopropyl sulfonic acid and salts thereof; copolymers of (meth)acrylic acid and salts thereof, maleic acid, maleic acid anhydride, styrene sulfonic acid and salts thereof, vinyl sulfonic acid and salts thereof, allyl sulfonic acid and salts thereof, acrylamidopropyl sulfonic acid and salts thereof; chitosan; cationic starch; polylysine and salts thereof; homopolymers of diallyldimethyl ammonium chloride (DADMAC), diallyldimethyl ammonium bromide, diallyldimethyl ammonium sulfate, diallyldimethyl ammonium phosphates, dimethallyldimethyl ammonium chloride, diethylallyl dimethyl ammonium chloride, diallyl di(beta-hydroxyethyl) ammonium chloride, diallyl di(beta-ethoxyethyl) ammonium chloride, dimethylaminoethyl (meth)acrylate acid addition salts and quaternary salts, diethylaminoethyl (meth)acrylate acid addition salts and quaternary salts, 7-amino-3,7-dimethyloctyl (meth) acrylate acid addition salts and quaternary salts, N,N′-dimethylaminopropyl acrylamide acid addition salts and quaternary salts, allylamine, diallylamine, vinylamine, vinyl pyridine; and co-polymers of diallyldimethyl ammonium chloride (DADMAC), diallyldimethyl ammonium bromide, diallyldimethyl ammonium sulfate, diallyldimethyl ammonium phosphates, dimethallyldimethyl ammonium chloride, diethylallyl dimethyl ammonium chloride, diallyl di(beta-hydroxyethyl) ammonium chloride, diallyl di(beta-ethoxyethyl) ammonium chloride, dimethylaminoethyl (meth)acrylate acid addition salts and quaternary salts, diethylaminoethyl (meth)acrylate acid addition salts and quaternary salts; cocodimethylcarboxymethylbetaine; lauryldimethylcarboxymethylbetaine; lauryldimethyl-alpha-carboxyethylbetaine; cetyldimethylcarboxymethylbetaine; lauryl-bis-(2-hydroxyethyl)carboxymethylbetaine; stearyl-bis-(2-hydroxypropyl)carboxymethylbetaine; oleyldimethyl-gamma-carboxypropylbetaine; lauryl-bis-(2-hydroxypropyl)alpha-carboxyethylebetaine; cocodimethylsulfopropylbetaine; stearyldimethylsulfopropylbetaine; lauryl-bis-(2-hydroxyethyl) sulfopropylbetaine; sodium dodecylsulfate (SDS); Surfynol 104, dioctyl sulfosuccinate sodium salt; sodium lauryl ether sulfate; polyethylene glycol branched-nonylphenyl ether sulfate ammonium salt; disodium 2-dodecyl-3-(2-sulfonatophenoxy); PEG25-PABA; polyethylene glycol mono-C₁₀₋₁₆-alkyl ether sulfate sodium salt; (2-N-butoxyethoxy)acetic acid; hexadecylbenzene sulfonic acid; cetyltrimethylammonium hydroxide; dodecyltrimethylammonium hydroxide; dodecyltrimethyl ammonium chloride; cetyltrimethyl ammonium chloride; N-Alkyl-N-benzyl-N,N-dimethylammonium chloride; dodecylamine; polyoxyethylene lauryl ether; dodecenylsuccinic acid monodiethanol amide; ethylenediamine tetrakis (ethoxylate-block-propoxylate); PolyFox PF-159 (OMNOVA Solutions), polyethylene glycol) (“PEG”), poly(propylene glycol) (“PPG”), ethylene oxide/propylene oxide block copolymers such as Pluronic F-127 (BASF), a polysorbate polyoxyethylene (20) sorbitan monooleate (Tween 80), polyoxyethylene (20) sorbitan monostearate (Tween 60), polyoxyethylene (20) sorbitan monopalmitate (Tween 40), polyoxyethylene (20) sorbitan monolaurate (Tween 20)), polyoxypropylene/polyoxyethylene block copolymers (e.g., Pluronic L31, Plutonic 31R1, Pluronic 25R2 and Pluronic 25R4), decylphosphonic acid, dodecylphosphonic acid (DDPA), tetradecylphosphonic acid, hexadecylphosphonic acid, bis(2-ethylhexyl)phosphate, octadecylphosphonic acid, perfluoroheptanoic acid, prefluorodecanoic acid, trifluoromethanesulfonic acid, phosphonoacetic acid, dodecylbenzenesulfonic acid (DDBSA), other R¹ benzene sulfonic acids or salts thereof (where the R¹ is a straight-chained or branched C₈-C₁₈ alkyl group), dioctadecyl hydrogen phosphate, octadecyl dihydrogen phosphate, dodecylamine, dodecenylsuccinic acid monodiethanol amide, lauric acid, palmitic acid, oleic acid, juniperic acid, 12 hydroxystearic acid, octadecylphosphonic acid (ODPA), dodecyl phosphate.

Exemplary non-ionic surfactants include, but are not limited to, ethoxylated hydrophobic alcohols such as C₈-C₂₀ alkyl ethers such as polyoxyethylene lauryl ether, monodiethanol amide, ethylenediamine tetrakis (ethoxylate-block-propoxylate) tetrol, polyethylene glycols, polypropylene glycols, polyethylene or polypropylene glycol ethers, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched, Polyoxyethylene (40) nonylphenylether, branched, dinonylphenyl polyoxyethylene, nonylphenol alkoxylates, polyoxyethylene sorbitol hexaoleate, polyoxyethylene sorbitol tetraoleate, polyethylene glycol sorbitan monooleate, sorbitan monooleate, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazanes, silicone-polyether copolymers, and ethoxylated fluorosurfactants.

Cationic surfactants contemplated include, but are not limited to, cetyl trimethylammonium bromide (CTAB), heptadecanefluorooctane sulfonic acid, tetraethylammonium, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, and oxyphenonium bromide, guanidine hydrochloride (C(NH₂)₃Cl) or triflate salts such as tetrabutylammonium trifluoromethanesulfonate, dimethyldioctadecylammonium chloride, dimethyldihexadecylammonium bromide, di(hydrogenated tallow)dimethylammonium chloride, and polyoxyethylene (16) tallow ethylmonium ethosulfate.

Anionic surfactants contemplated include, but are not limited to, poly(acrylic acid sodium salt), ammonium polyacrylate, sodium polyoxyethylene lauryl ether, sodium dihexylsulfosuccinate, sodium dodecyl sulfate, dioctylsulfosuccinate salt, 2-sulfosuccinate salts, 2,3-dimercapto-1-propanesulfonic acid salt, dicyclohexyl sulfosuccinate sodium salt, sodium 7-ethyl-2-methyl-4-undecyl sulfate, phosphate fluoro surfactants, fluoro surfactants, and polyacrylates.

Zwitterionic surfactants include, but are not limited to, acetylenic diols or modified acetylenic diols, ethylene oxide alkylamines, N,N-dimethyldodecylamine N-oxide, sodium cocaminpropinate, 3-(N,N-dimethylmyristylammonio)propanesulfonate, and (3-(4-heptyl)phenyl-3-hydroxypropyl)dimethylammoniopropanesulfonate, decylphosphonic acid, dodecylphosphonic acid (DDPA), tetradecylphosphonic acid, hexadecylphosphonic acid, bis(2-ethylhexyl)phosphate, octadecylphosphonic acid, perfluoroheptanoic acid, prefluorodecanoic acid, trifluoromethanesulfonic acid, and phosphonoacetic acid.

In another embodiment, the cleaning additive is chosen from ethylene glycol monobutyl ether, diethylene glycol monobutyl ether, propylene glycol monobutyl ether, dipropylene glycol monobutyl ether, ethylene glycol monohexyl ether, diethylene glycol monohexyl ether, triethylene glycol monobutyl ether, ethylene glycol monophenyl ether, diethylene glycol monophenyl ether, propylene glycol monophenyl ether, dimethylsulfoxide, sulfolane, poly(styrene sulfonic acid) or salts thereof, poly(vinyl pyrrolidone), poly(vinyl alcohol), poly(acrylic acid) and salts thereof, polyacrylic acid copolymers and salts thereof, poly(ethylene glycol), polyethylene glycol-co-polypropylene glycol, hydroxyethyl cellulose, poly(2-acrylamido-2-methyl-1-propanesulfonic acid) and copolymers thereof, polydiallyldimethylammonium chloride, poly(dimethylaminoethylmethacrylate) and copolymers thereof, poly(trimethylaminoethylmethacryate) salts and copolymers thereof, ethoxylated alcohols or phenols, ethoxylated fatty acid sugars, dodecylbenzene sulfonic acid, lauryl sulfonic acid, octanoic acid, nonanoic acid, decanoic acid, undecylic acid, dodecanoic acid, benzyldimethyldocecylammonium chloride, benzyldimethyldocecylammonium hydroxide, and trimethyldodecylammonium chloride.

When present, the amount of cleaning compound in the composition is in one embodiment, in a range from about 0.001 wt % to about 20 wt %, based on the total weight of the composition. In another embodiment, the cleaning additive is present in an amount of from about 0.1 wt % to about 10 wt %, based on the total weight of the composition, and in another embodiment, in an amount of from about 0.5 wt % to about 5 wt %.

In another embodiment, the composition further comprises an additional corrosion inhibitor which is different from component d) herein. Such optional additional corrosion inhibitor(s) are chosen from 5-aminotetrazole, 5-phenyl-benzotriazole, 1H-tetrazole-5-acetic acid, 1-phenyl-2-tetrazoline-5-thione, benzimidazole, methyltetrazole, Bismuthiol I, cytosine, guanine, thymine, pyrazoles, iminodiacetic acid (IDA), propanethiol, benzohydroxamic acids, citric acid, ascorbic acid, 5-amino-1,3,4-thiadiazole-2-thiol (ATDT), benzotriazole (BTA), 1,2,4-triazole (TAZ), tolyltriazole, 5-methyl-benzotriazole (mBTA), 5-phenyl-benzotriazole, 5-nitro-benzotriazole, benzotriazole carboxylic acid, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole (3-ATA), 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-amino-1,2,4-triazole (5-ATA), sodium dedecyl sulfate (SDS), ATA-SDS, 3-amino-5-mercapto-1,2,4-triazole, pentylenetetrazole, 5-phenyl-1H-tetrazole, 5-benzyl-1H-tetrazole, Ablumine O, 2-benzylpyridine, succinimide, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, 4-methyl-4H-1,2,4-triazole-3-thiol, 4-amino-4H-1,2,4-triazole, 3-amino-5-methylthio-1H-1,2,4-triazole, benzothiazole, imidazole, indiazole, adenine, succinimide, adenosine, carbazole, saccharin, uric acid, benzoinoxime, cationic quaternary salts (e.g., benzalkonium chloride, benzyldimethyldodecylammonium chloride, myristyltrime thylammonium bromide, dodecyltrimethylammonium bromide, hexadecylpyridinium chloride, Aliquat 336 (Cognis), benzyldimethylphenylammonium chloride, Crodaquat TES (Croda. Inc.), Rewoquat CPEM (Witco), hexadecyltrimethylammonium p-toluenesulfonate, hexadecyltrimethylammonium hydroxide, 1-methyl-1′-tetradecyl-4,4′-bipyridium dichloride, alkyltrimethylammonium bromide, amprolium hydrochloride, benzethonium hydroxide, benzethonium chloride, benzyldimethylhexadecylammonium chloride, benzyldimethyltetradecylammonium chloride, benzyldodecyldimethylammonium bromide, benzyldodecyldimethylammonium chloride, cetylpyridinium chloride, choline p-toluenesulfonate salt, dimethyldioctadecylammonium bromide, dodecylethyldimethylammonium bromide, dodecyltrimethylammonium chloride, decyltrimethylammonium chloride (DTAC), ethylhexadecyldimethylammonium bromide, Girard's reagent, hexadecyl(2-hydroxyethyl)dimethylammonium dihydrogen phosphate, dexadecylpyridinium bromide, hexadecyltrimethylammonium bromide, hexadecyltrimethylammonium chloride, methylbenzethonium chloride, Hyamine® 1622, Luviquat™, N,N′,N′-polyoxyethylene (10)-N-tallow-1,3-diaminopropane liquid, oxyphenonium bromide, tetraheptylammonium bromide, tetrakis(decyl)ammonium bromide, thonzonium bromide, tridodecylammonium chloride, trimethyloctadecylammonium bromide, 1-methyl-3-n-octylimidazolium tetrafluoroborate, 1-decyl-3-methylimidazolium tetrafluoroborate, 1-decyl-3-methylimidazolium chloride, tridodecylmethylammonium bromide, dimethyldistearylammonium chloride, cetyltrimethylammonium bromide, myristyltrimethylammonium bromide, and hexamethonium chloride and combinations thereof hexadecyltrimethylammonium p-toluenesulfonate, hexadecyltrimethylammonium hydroxide, 1-methyl-1′-tetradecyl-4,4′-bipyridium dichloride, alkyltrimethylammonium bromide, amprolium hydrochloride, benzethonium hydroxide, benzethonium chloride, benzylditnethylhexadecylammonium chloride, benzyldimethyltetradecylammonium chloride, benzyldodecyldimethylammonium bromide, benzyldodecyldimethylammonium chloride, cetylpyridinium chloride, choline p-toluenesulfonate salt, dimethyldioctadecylammonium bromide, dodecylethyldime thylammonium bromide, dodecyltrimethylammonium chloride, ethylhexadecyldimethylammonium bromide, Girard's reagent, hexadecyl(2-hydroxyethyl)dimethylammonium dihydrogen phosphate, dexadecylpyridinium bromide, hexadecyltrimethylammonium bromide, hexadecyltrimethylammonium chloride, methylbenzethonium chloride, Hyamine® 1622, Luviquat™, N,N′,N′-polyoxyethylene (10)-N-tallow-1,3-diaminopropane liquid, oxyphenonium bromide, tetraheptylammonium bromide, tetrakis(decyl)ammonium bromide, thonzonium bromide, tridodecylammonium chloride, trimethyloctadecylammonium bromide, 1-methyl-3-n-octylimidazolium tetrafluoroborate, 1-decyl-3-methylimidazolium tetrafluoroborate. 1-decyl-3-methylimidazolium chloride, tridodecylmethylammonium bromide, dimethyldistearylammonium chloride, cetyltrimethylammonium bromide, myristyltrimethylammonium bromide, and hexamethonium chloride), anionic surfactants (e.g., dodecylbenzenesulfonic acid, sodium dodecylbenzenesulfonate, dodecylphosphonic acid (DDPA), acetic acid, acetone oxime, acrylic acid, adipic acid, alanine, arginine, asparagine, aspartic acid, betaine, dimethyl glyoxime, formic acid, fumaric acid, gluconic acid, glutamic acid, glutamine, glutaric acid, glyceric acid, glycerol, glycolic acid, glyoxylic acid, histidine, iminodiacetic acid, isophthalic acid, itaconic acid, lactic acid, leucine, lysine, maleic acid, maleic anhydride, malic acid, malonic acid, mandelic acid, 2,4-pentanedione, phenylacetic acid, phenylalanine, phthalic acid, proline, propionic acid, pyrocatecol, pyromellitic acid, quinic acid, serine, sorbitol, succinic acid, tartaric acid, terephthalic acid, trimellitic acid, trimesic acid, tyrosine, valine, xylitol, oxalic acid, picolinic acid, 1,3-cyclopentanedione, catechol, pyrogallol, resorcinol, hydroquinone, cyanuric acid, barbituric acid, 1,2-dimethylbarbituric acid, pyruvic acid, propanethiol, benzohydroxamic acids, 2,5-dicarboxypryidine, 4-(2-hydroxyethyl)morpholine (HEM), N-aminoethylpiperazine (N-AEP), ethylenediaminetetraacetic acid (EDTA), 1,2-cyclohexanediamine-N,N,N′,N′-tetraacetic acid (CDTA), N-(hydroxyethyl)-ethylenediaminetriacetic acid (HEdTA), iminodiacetic acid (IDA), 2-(hydroxyethyl)iminodiacetic acid (HIDA), nitrilotriacetic acid, thiourea, 1,1,3,3-tetramethylurea, urea, urea derivatives, glycine, cysteine, glutamic acid, isoleucine, methionine, piperidine, N-(2-aminoethyl) piperidine, pyrrolidine, threonine, tryptophan, salicylic acid, p-toluenesulfonic acid, salicylhyroxyamic, 5-sulfosalicylic acid, triazole, aminotriazole, dimethylpropargyl alcohol, lauroyl sarcosine, steroyl sarcosine, saccharine, boric acid, 3-hydroxy-2-naphthoic acid, malonic acid, iminodiacetic acid, ammonium pentaborate, urea, methyltriethoxysilane, 4-methylpyrazole, pyrazole, 2-amino-thiazole, adenosine, 2-amino-1,3,4-thiadiazole, 5-amino-1H-tetrazole, adenine, pterine, pyrimidine, pyrazine, cytosine, pyridazine, 1H-pyrazole-3-carboxylic acid, 1H-pyrazole-4-carboxylic acid, 3-amino-5-hydroxy-1H-pyrazole, 3-amino-5-methyl-1H-pyrazole, 3-amino-5-tert-butyl-1H-pyrazole, 2-amino-methylthiazole, 2-mercaptothiazole, 2,5-dimercapto-1,3,4-thiadiazole, 2-mercapto-5-methyl-1,3,4-thiadiazole, 2-aminothiazole-5-carbonitrile, 2-aminothiazole-5-carboxaldehyde, ethyl 2-aminothiazole-4-carboxylate, 1,2,3-triazole, 1,2,4-triazole, imidazole, 3-amino-1,2,4-triazole derivatives thereof, and combinations thereof.

In another embodiment, the composition further comprises a biocide such as the isothiazolinones.

In another embodiment, the composition is substantially free of oxidizers and fluorides.

The range of weight percent ratios of the components described herein will cover all possible concentrated or diluted embodiments of the composition. Towards that end, in one embodiment, a concentrated removal composition is provided that can be diluted for use as a cleaning solution. A concentrated composition, or “concentrate,” advantageously permits a user (e.g. a CMP process engineer) to dilute the concentrate to the desired strength and pH at the point of use. Dilution of the concentrated aqueous removal composition may be in a range from about 1:1 to about 2500:1, or about 5:1 to about 200:1, or about 20:1 to about 120:1, wherein the aqueous removal composition is diluted at or just before use with solvent, e.g., deionized water. It is to be appreciated by one skilled in the art that following dilution, the range of weight percent ratios of the components disclosed herein should remain unchanged.

The compositions described herein are thus useful in applications including, but not limited to, post-etch residue removal, post-ash residue removal surface preparation, post-plating cleaning and post-CMP residue removal. In addition to cleaning of aluminum-containing components, the cleaning compositions described herein are in some embodiments useful for the cleaning and protection of other metals (e.g., copper-containing and cobalt-containing) microelectronic device structures.

The cleaning compositions are easily formulated by simple addition of the respective ingredients and mixing to homogeneous condition. Furthermore, the compositions may be readily formulated as single-package formulations or multi-part formulations that are mixed at or before the point of use, e.g., the individual parts of the multi-part formulation may be mixed at the tool or in a storage tank upstream of the CMP tool. The concentrations of the respective ingredients may be widely varied in specific multiples of the composition, i.e., more dilute or more concentrated, and it will be appreciated that the compositions described herein can variously and alternatively comprise, consist or consist essentially of any combination of ingredients consistent with the disclosure herein.

Accordingly, another aspect relates to a kit including, in one or more containers, one or more components adapted to form the cleaning compositions described herein. The kit may include, in one or more containers, water; an etchant compound; a pH adjustor; and one or more compounds of the formula (I) or (II) as set forth herein, for combining with additional solvent (e.g., water) at the fab or the point of use. Of course, the kit may further include one or more of the optional ingredients recited above. The containers of the kit must be suitable for storing and shipping the compositions and may be, for example, NOWPak® containers (Entegris, Inc., Billerica, Mass., USA).

The one or more containers which contain the components of the aqueous cleaning composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool.

As applied to microelectronic manufacturing operations, the cleaning compositions described herein are usefully employed for removing residue and contaminants, including particles, post-CMP residue, post-ash residue, and post-etch residue, from the surface of the microelectronic device. Advantageously, the disclosed cleaning compositions described herein show improved cobalt compatibility relative to alternative cleaning compositions previously described in the art. Thus, the present disclosure further relates to a method of removing residue and contaminants from a microelectronic device having said residue and contaminants thereon using the cleaning compositions described herein.

The method comprises contacting a microelectronic device with the disclosed cleaning composition for a time sufficient to at least partially clean the residue and contaminants from the microelectronic device. In use, the composition is typically contacted with the device for a time of from about 5 sec to about 10 minutes, preferably about 1 sec to 20 min, preferably about 15 sec to about 5 min at temperature in a range of from about 20° C. to about 90° C., preferably about 20° C. to about 50° C. Such contacting times and temperatures are illustrative, and any other suitable time and temperature conditions may be employed that are efficacious to at least partially remove the residue and contaminants from the device, within the broad practice of the method. Thus, in another aspect, the invention provides a method for removing residue and contaminants from a microelectronic device substrate having the residue and contaminants thereon, the method comprising contacting the microelectronic device substrate with the composition of the first aspect, as set forth above, for a time sufficient to at least partially clean the residue and contaminants from the microelectronic device substrate.

“At least partially clean” and “substantial removal” both correspond to at removal of at least 85% of the silica particles present on the device prior to particle removal, more preferably at least 90%, even more preferably at least 95%, and most preferred at least 99%.

After contacting the device and removing the target desired residues and/or contaminants, the cleaning composition may be readily removed from the device to which it has previously been applied, as may be desired and efficacious in a given end use application of the compositions described herein. For example, a rinse solution may be used, wherein the rinse solution includes deionized water. Thereafter, the device may be dried using nitrogen or a spin-dry cycle, as is known in the art.

Another aspect of the present invention relates to the improved microelectronic devices made according to the methods described herein and to products containing such microelectronic devices. Another aspect relates to a recycled composition, wherein the composition may be recycled until particle and/or contaminant loading reaches the maximum amount the composition may accommodate, as readily determined by one skilled in the art. As such, the composition disclosed herein may include residue and/or contaminants. The residue and contaminants may be dissolved in the composition. Alternatively, the residue and contaminants may be suspended in the composition. In certain embodiments, the residue includes post-CMP residue, post-etch residue, post-ash residue, contaminants, or combinations thereof. A still further aspect relates to methods of manufacturing an article comprising a microelectronic device, said method comprising contacting the microelectronic device with the compositions of the invention for a time sufficient to remove residue and/or contaminants from the microelectronic device and incorporating the cleaned microelectronic device into an article. Another aspect relates to the article produced by this method.

As noted above, the compositions of the invention are useful in post-CMP cleaning operations. The Examples below and the Figures illustrate that the compositions were also found to have a nominal etching effect on aluminum, copper, and cobalt surfaces under conditions which mimic the exposure of a microelectronic device substrate to post-CMP cleaning.

### Examples

Base Composition: A base composition as set forth in Table 1 was prepared:

TABLE 1

| | | | Component | Added |
|---|---|---|---|---|
| Blend | | Solvent | assay | weight |
| order | Components | (if in solution) | weight percent | percent |
| 1 | Deionized water | N/A | 100 | 55.42 |
| 2 | Tri-ethanolamine | N/A | 100 | 20.56 |
| 3 | Ascorbic acid | N/A | 100 | 11.21 |
| 4 | Choline hydroxide | DIW | 46.7 | 12.81 |

### General Procedure for Base Composition

To 50 grams of deionized water was added 20.56 grams of triethanolamine. To this solution was added 11.21 grams of ascorbic acid, followed by choline hydroxide to adjust the pH to about 9.

This Base Composition was then combined with the following aluminum corrosion inhibitors to form Compositions 1 through 14.
Composition 1—Base Composition plus phenylphosphonic acid (CAS No. 1571-33-1)
Composition 2—Base Composition plus phytic acid (CAS No. 83-86-3)
Composition 3—Base Composition plus octylphosphonic acid (CAS No. 4724-48-5)
Composition 4—Base Composition plus tetraisopropyl vinylidenediphosphonate (CAS No. 48074-47-1)
Composition 5—Base Composition plus potassium di-tert-butylphosphate (CAS No. 33494-80-3)
Composition 6—Base Composition plus humic acid (CAS No. 1415-93-6)
Composition 7—Base Composition plus ethylphosphonic acid (CAS No. 6779-09-5)
Composition 8—Base Composition plus methylenediphosphonic acid (CAS No. 1984-15-2)
Composition 9—Base Composition plus 1,10-decyldiphosphonic acid (CAS No. 5943-21-5)
Composition 10—Base Composition plus octylphosphonic acid (CAS No. 4724-48-5)
Composition 11—Base Composition plus hexylphosphonic acid (CAS No. 4721-24-8)
Composition 12—Base Composition plus octadecylphosphonic acid (CAS No. 4724-47-4)
Composition 13—Base Composition plus n-dodecylphosphonic acid (CAS No. 5137-70-2)
Composition 14—Base Composition plus mono-N-dodecyl phosphate (CAS No. 2627-35-2)

All compositions were tested for AlCu etch rate as a measure of an amount of AlCu metal that is removed from a surface upon exposing the surface to Compositions 1 through 46 above at pH=9. For these experiments, the AlCu wafer was a 99.5% Al and 0.5% Cu alloy. AlCu metal film thickness was measured by use of X-ray fluorescence (XRF) before and after a 15 minute cleaning process at 30° C. and 500 rpm agitation. As shown in Table 2 below, the compositions of the invention provided lower etch rates of AlCu material as compared to the Base Composition.

TABLE 2

| | AlCu Etch Rate | Co Etch Rate | Cu Etch Rate |
|---|---|---|---|
| Composition No. | (Å/minute) | (Å/minute) | (Å/minute) |
| Base Composition | 16.18 | 5.45 | 0.89 |
| 1 | 8.98 | | |
| 2 | 0.50 | 9.13 | 1.20 |
| 3 | 8.86 | | |
| 4 | 11.86 | | |
| 5 | 7.38 | | |
| 6 | 4.55 | | |
| 7 | 0.12 | 15.68 | 4.91 |
| 8 | 0.09 | 3.04 | 0.90 |
| 9 | 4.30 | 2.85 | 0.96 |
| 10 | 5.82 | | |
| 11 | 1.70 | | |
| 12 | 0.22 | | |
| 13 | −0.06 | | |
| 14 | 0.22 | | |

Compositions 1 through 14 showed no corrosion inhibition of an AlCu surface at pH=12 and 14.

In a first aspect, the invention provides a composition comprising:
a) water;
b) an etchant compound;
c) a reducing agent; and
d) an aluminum, cobalt, or copper corrosion inhibitor chosen from compounds having the formula

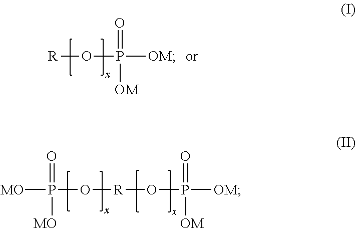

wherein each x is independently 0 or 1, R is an aryl or arylene group or a monovalent or divalent C₁-C₂₀ hydrocarbyl group, and M is chosen from hydrogen, a C₁-C₆ alkyl group, ammonium, or an alkali metal cation, and wherein the pH of the composition is greater than about 8.

In a second aspect, the invention provides the composition of the first aspect, wherein the C₁-C₂₀ hydrocarbyl group is chosen from linear or branched alkyl or alkylene groups.

In a third aspect, the invention provides the composition of the first aspect, wherein the C₁-C₂₀ hydrocarbyl group is chosen from cycloalkyl, cycloalkylene, phenyl, or phenylene groups.

In a fourth aspect, the invention provides the composition of the first aspect, wherein the compounds of formula (I) and (II) are chosen from
phenylphosphonic acid;
phytic acid;
(12-phosphonododecyl)phosphonic acid;
n-dodecylphosphonic acid;
6-phosphonohexanoic acid;
1,4-phenylenebis(phosphonic acid);
poly(vinylphosphonic acid);
octylphosphonic acid;
tetraisopropyl vinylidenediphosphonate;
potassium di-tert-butylphosphate;
ethylphosphonic acid;
methylenediphosphonic acid;
1,10-decyldiphosphonic acid;
octylphosphonic acid;
hexylphosphonic acid;
octadecylphosphonic acid;
n-dodecylphosphonic acid; and
mono-N-dodecyl phosphate.

In a fifth aspect, the invention provides the composition of any one of the first four aspects, wherein the etchant compound is chosen from monoethanolamine, triethanolamine, sulfuric acid, citric acid and combinations thereof.

In a sixth aspect, the invention provides the composition of any one of the first four aspects, wherein the etchant compound is triethanolamine.

In a seventh aspect, the invention provides the composition of any one of the first five aspects, further comprising one or more pH adjustors.

In an eighth aspect, the invention provides the composition of the seventh aspect, wherein the pH adjustor is chosen from tetramethylammonium hydroxide, tetraethylammonium hydroxide, choline hydroxide, ammonium hydroxide, and potassium hydroxide.

In a ninth aspect, the invention provides the composition of the seventh or eighth aspects, wherein the pH adjustor is choline hydroxide.

In a tenth aspect, the invention provides the composition of any one of the first nine aspects, wherein the pH is less than about 14.

In an eleventh aspect, the invention provides the composition of the first aspect, wherein the pH is about 8.5 to about 12.

In a twelfth aspect, the invention provides the composition of the first aspect, wherein component d) is an aluminum corrosion inhibitor and the pH is about 8 to about 11.

In a thirteenth aspect, the invention provides the composition of the first aspect, wherein component d) is a cobalt corrosion inhibitor and the pH is about 8 to about 13.5.

In a fourteenth aspect, the invention provides the composition of any one of the first thirteen aspects, further comprising one or more cleaning additives.

In a fifteenth aspect, the invention provides the composition of any one of the first fourteen aspects, further comprising a second corrosion inhibitor.

In a sixteenth aspect, the invention provides the composition of any one of the first fifteen aspects, wherein the reducing agent is chosen from hydrophosphorous acid, phosphorous acid, sulfurous acid, sodium metabisulfite, ammonium metabisulfite, potassium metabisulfite, ascorbic acid, L(+)-ascorbic acid, isoascorbic acid, hydroxylamine, hydroxylamine salts, dimethylhydroxylamine, diethylhydroxylamine, reducing sugars chosen from galactose, xylose, glucose, fructose, lactose and maltose, hydroquinone, catechol, tetrahydrofulvalene, N,N-dimethylanilinebenzylamine, and combinations thereof.

In a seventeenth aspect, the invention provides the composition of any one of the first sixteen aspects, wherein the reducing agent is ascorbic acid.

In an eighteenth aspect, the invention provides the composition of the fourteenth aspect, wherein the cleaning additive is chosen from ethylene glycol monobutyl ether, diethylene glycol monobutyl ether, propylene glycol monobutyl ether, dipropylene glycol monobutyl ether, ethylene glycol monohexyl ether, diethylene glycol monohexyl ether, triethylene glycol monobutyl ether, ethylene glycol monophenyl ether, diethylene glycol monophenyl ether, propylene glycol monophenyl ether, dimethylsulfoxide, sulfolane, poly(styrene sulfonic acid) or salts thereof, poly(vinyl pyrrolidone), poly(vinyl alcohol), poly(acrylic acid) and salts thereof, polyacrylic acid copolymers and salts thereof, poly(ethylene glycol), polyethylene glycol-co-polypropylene glycol, hydroxyethyl cellulose, poly(2-acrylamido-2-methyl-1-propanesulfonic acid) and copolymers thereof, polydiallyldimethylammonium chloride, poly(dimethylaminoethylmethacrylate) and copolymers thereof, poly(trimethylaminoethylmethacryate) salts and copolymers thereof, ethoxylated alcohols or phenols, ethoxylated fatty acid sugars, dodecylbenzene sulfonic acid, lauryl sulfonic acid, octanoic acid, nonanoic acid, decanoic acid, undecylic acid, dodecanoic acid, benzyldimethyldocecylammonium chloride, benzyldimethyldocecylammonium hydroxide, and trimethyldodecylammonium.

In a nineteenth aspect, the invention provides a method for removing residue and contaminants from a microelectronic device substrate having the residue and contaminants thereon, the method comprising contacting the microelectronic device substrate with the composition of any one of the first through seventeenth aspects, for a time sufficient to at least partially clean the residue and contaminants from the microelectronic device substrate.

In a twentieth aspect, the invention provides a kit, comprising in two or more containers, two or more of the components a), b), c), and d), of any one of the first eighteen aspects.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A composition comprising:
a) water;
b) an etchant compound;
c) a reducing agent; and
d) an aluminum, cobalt, or copper corrosion inhibitor chosen from compounds having the formula 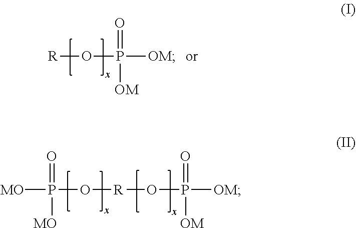
wherein each x is independently 0 or 1, R is an aryl or arylene group or a monovalent or divalent C₁-C₂₀ hydrocarbyl group, and M is chosen from hydrogen, a C₁-C₆ alkyl group, ammonium, or an alkali metal cation, and wherein the pH of the composition is greater than about 8.

2. The composition of claim 1, wherein the C₁-C₂₀ hydrocarbyl group is chosen from linear or branched alkyl or alkylene groups.

3. The composition of claim 1, wherein the C₁-C₂₀ hydrocarbyl group is chosen from cycloalkyl, cycloalkylene, phenyl, or phenylene groups.

4. The composition of claim 1, wherein the compounds of formula (I) and (II) are chosen from
phenylphosphonic acid;
phytic acid;
(12-phosphonododecyl)phosphonic acid;
n-dodecylphosphonic acid;
6-phosphonohexanoic acid;
1,4-phenylenebis(phosphonic acid);
poly(vinylphosphonic acid);
octylphosphonic acid;
tetraisopropyl vinylidenediphosphonate;
potassium di-tert-butylphosphate;
ethylphosphonic acid;
methylenediphosphonic acid;
1,10-decyldiphosphonic acid;
octylphosphonic acid;
hexylphosphonic acid;
octadecylphosphonic acid;
n-dodecylphosphonic acid; and
mono-N-dodecyl phosphate.

5. The composition of claim 1, wherein the etchant compound is chosen from monoethanolamine, triethanolamine, sulfuric acid, citric acid and combinations thereof.

6. The composition of claim 1, wherein the etchant compound is triethanolamine.

7. The composition of claim 1, further comprising one or more pH adjustors.

8. The composition of claim 7, wherein the pH adjustor is chosen from tetramethylammonium hydroxide, tetraethylammonium hydroxide, choline hydroxide, ammonium hydroxide, and potassium hydroxide.

9. The composition of claim 7, wherein the pH adjustor is choline hydroxide.

10. The composition of claim 1, wherein the pH is less than about 14.

11. The composition of claim 1, wherein the pH is about 8.5 to about 12.

12. The composition of claim 1, wherein component d) is an aluminum corrosion inhibitor and the pH is about 8 to about 11.

13. The composition of claim 1, wherein component d) is a cobalt corrosion inhibitor and the pH is about 8 to about 13.5.

14. The composition of claim 1, further comprising one or more cleaning additives.

15. The composition of claim 1, further comprising a second corrosion inhibitor.

16. The composition of claim 1, wherein the reducing agent is chosen from hydrophosphorous acid, phosphorous acid, sulfurous acid, sodium metabisulfite, ammonium metabisulfite, potassium metabisulfite, ascorbic acid, L(+)-ascorbic acid, isoascorbic acid, hydroxylamine, hydroxylamine salts, dimethylhydroxylamine, diethylhydroxylamine, reducing sugars chosen from galactose, xylose, glucose, fructose, lactose and maltose, hydroquinone, catechol, tetrahydrofulvalene, N,N-dimethylanilinebenzylamine, and combinations thereof.

17. The composition of claim 1, wherein the reducing agent is ascorbic acid.

18. The composition of claim 13, wherein the cleaning additive is chosen from ethylene glycol monobutyl ether, diethylene glycol monobutyl ether, propylene glycol monobutyl ether, dipropylene glycol monobutyl ether, ethylene glycol monohexyl ether, diethylene glycol monohexyl ether, triethylene glycol monobutyl ether, ethylene glycol monophenyl ether, diethylene glycol monophenyl ether, propylene glycol monophenyl ether, dimethylsulfoxide, sulfolane, poly(styrene sulfonic acid) or salts thereof, poly(vinyl pyrrolidone), poly(vinyl alcohol), poly(acrylic acid) and salts thereof, polyacrylic acid copolymers and salts thereof, poly(ethylene glycol), polyethylene glycol-co-polypropylene glycol, hydroxyethyl cellulose, poly(2-acrylamido-2-methyl-1-propanesulfonic acid) and copolymers thereof, polydiallyldimethylammonium chloride, poly(dimethylaminoethylmethacrylate) and copolymers thereof, poly(trimethylaminoethylmethacryate) salts and copolymers thereof, ethoxylated alcohols or phenols, ethoxylated fatty acid sugars, dodecylbenzene sulfonic acid, lauryl sulfonic acid, octanoic acid, nonanoic acid, decanoic acid, undecylic acid, dodecanoic acid, benzyldimethyldocecylammonium chloride, benzyldimethyldocecylammonium hydroxide, and trimethyldodecylammonium chloride.

19. A method for removing residue and contaminants from a microelectronic device substrate having the residue and contaminants thereon, the method comprising contacting the microelectronic device substrate with the composition of claim 1, for a time sufficient to at least partially clean the residue and contaminants from the microelectronic device substrate.

20. A kit, comprising in two or more containers, two or more of the components a), b), c), and d) of claim 1.
